(19) United States
(12) Patent Application Publication
(10) Pub. No.: US 2008/0089073 A1
(43) Pub. Date: Apr. 17, 2008

(54) Dynamic Liquid Crystal Gel Holograms

(75) Inventor: Rifat Ata Mustafa Hikmet, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS, N.V., EINDHOVEN (NL)

(21) Appl. No.: 11/719,859

(22) PCT Filed: Nov. 21, 2005
(86) PCT No.: PCT/IB05/53846

§ 371 Date: Nov. 12, 2007

(30) Foreign Application Priority Data
Nov. 25, 2004 (EP) 04106070.8

(51) Int. Cl. G03H 1/18; F21V 5/00; G02B 5/32; G02F 1/03; G03F 7/00

(52) U.S. Cl. 362/311; 204/157.4; 359/15; 430/2; 430/20

(57) ABSTRACT

A dynamic hologram is formed in anisotropic liquid crystal (LC) gel materials. By applying an electric field, the orientation of part of the liquid crystals can be altered and the hologram can be turned on and off. Using LC gels allows for holographic elements with no diffraction in the voltage off state so that the hologram appears only during application of an electric field. Also, the anisotropic LC gels maintain polarization dependence. The dynamic holograms are suitable in e.g. dynamic holographic optical components whereby an optical function can be included/excluded in a beam path without introducing or removing elements.

### FIELD OF THE INVENTION

The invention relates to dynamic holograms formed in liquid crystal materials. By applying an electric field, the orientation of part of the liquid crystals can be altered and the hologram can be turned on and off. The invention is suitable in e.g. dynamic holographic optical components whereby an optical function can be included/excluded in a beam path without introducing or removing elements.

### BACKGROUND OF THE INVENTION

Conventional holograms known in the literature are static holograms. Once the hologram is made its optical characteristics cannot be changed. Holograms that can be electrically controlled have been made by combining the advantages of liquid crystals with volume holographic gratings. First, a holographic transmission grating is formed by exposing a photo polymerizable material with a conventional two-beam apparatus for forming interference patterns inside the material. After exposure, the material is processed to produce voids in regions of the greatest exposure and the voids are infused with liquid crystals. Unfortunately, these materials are complex to manufacture and do not offer flexibility for in situ control over liquid crystal domain size, shape, density, or ordering.

Switchable liquid crystal holograms have also been fabricated in polymer dispersed liquid crystal (PDLC) materials. U.S. Pat. No. 5,942,157 discloses a PDLC material comprising a homogeneous mixture of a nematic liquid crystal and a multifunctional pentaacrylate monomer, in combination with photoinitiator, coinitiator and cross-linking agent. The PDLC material is exposed to coherent light to produce an interference pattern inside the material. Photopolymerization of the PDLC material produces a hologram of clearly separated liquid crystal domains and cured polymer domains.

### SUMMARY OF THE INVENTION

It would be advantageous if it was possible to provide improved dynamic holographic elements having simple fabrication, easy operation, high transparency, low diffraction in an off-state, high diffraction efficiency in an on-state, and well defined birefringent properties.

PDLC materials applied in switchable holographic elements in the prior art are isotropic systems with no macroscopic alignment. Although a PDLC solution comprises LC components, the mixture is not a LC since the other components disturb the LC characteristics and make the molecules randomly oriented.

Contrary to PDLC materials, LC gel materials are in an anisotropic liquid crystal phase before polymerization. In the present text, the LC gel material before polymerization will also be referred to as the LC pre-gel mixture. LC gel systems are polymer-stabilized, anisotropic liquid crystal phases wherein none of the constituents, in their concentration and state before polymerisation, had the ability to disturb the (refractive index) anisotropy or liquid crystal state of the phase.

The inventors of the present invention have found that by using an anisotropic LC pre-gel mixture instead of an isotropic pre-PDLC mixture, a holographic LC gel element that perform differently than holographic PDLC elements can be produced. The production involves a two-step illumination process, which results in new and surprising characteristics of the holographic element.

Accordingly, a first aspect of the invention provides a hologram formed by exposing an interference pattern of polymerizing light inside an anisotropic LC pre-gel material and thereafter exposing the bulk LC pre-gel material to flood polymerizing light.

A LC pre-gel mixture comprises the following components
a non-reactive LC host which does not undergo polymerization upon polymerization of the mixture;
monofunctional reactive (polymerizable) monomer, which forms a linear polymer upon polymerisation;
multifunctional reactive monomer which can copolymerize with the nonfunctional reactive mixture and form cross-linking upon polymerisation (also referred to as a cross linker); and
a photoinitiator.

The individual components do not need to be in a liquid crystal phase as long as they do not disturb the liquid crystal ordering of the overall mixture before or after polymerization. The LC host can be any commercially available LC mixture. Various types of functional groups may be chosen for polymerization of the monomers. The monofunctional polymerizable polymer may e.g. be mono acrylate, mono epoxy, mono vinyl ether. The multi functional polymer for crosslinking may e.g. be a di- or tri- (multi) acrylate, epoxy or vinylether. Thioleene systems with a functionality higher than three reactive groups may also be used. In a preferred embodiment, reactive molecules are chosen as mesogenic molecules which show the tendency to form liquid crystal phases. The photoinitiator may be any molecule, which initiate free-radical, cationic/anionic polymerization upon exposure to light.

LC pre-gel mixtures can be photo-polymerized by illuminating the material with polymerizing radiation, typically ultraviolet (UV) light. During polymerization, networks of cross-linked polymer chains are formed which reduces the tendency of the LC molecules to align in an exterior electric field. In the present context, polymerizing as a verb means to undergo or be subject to polymerization and, as an adjective, means the ability to cause or induce polymerization in a polymerizable medium.

According to a second aspect, the invention provides a method for forming a dynamic holographic element, the method comprising the steps of:
providing an anisotropic LC pre-gel mixture comprising:
   a non-reactive LC host;
   monofunctional polymerizable monomer;
   multifunctional reactive monomer; and
   a photoinitiator
illuminating parts of the LC pre-gel mixture with an interference pattern of polymerizing light forming high intensity regions and low or no intensity regions in the LC pre-gel mixture, and
illuminating the LC pre-gel mixture with polymerizing light to form an anisotropic LC gel.

During the first illumination step, the formation of high and low intensity regions in the LC gel phase, several processes are initiated. First, the photoinitiator molecules are split into radicals by the incident radiation. This reaction has a higher rate in the high intensity regions. This starts the polymerization reaction between the monomers and the cross-linking molecules. This reaction, as a consequence of the photoinitiator reaction, also have a higher rate in the high intensity regions, and a gradual depletion of monomers and/or the cross-linking molecules in the high intensity regions is initiated. If one of the polymerizing components is substantially less abundant than the other(s), it is only the concentration of this component which is significantly affected. This again results in a net diffusion of the less abundant polymerizing component from the low intensity regions to the high intensity regions according to Fick's law.

During the first illumination step, the initially homogeneous LC mixture become inhomogeneous with a larger concentration of polymerizing components in the high intensity regions. The composition of the LC gel phase and a scale of intensity variations in fringes of the interference pattern are preferably adapted to allow for efficient diffusion of polymerizing components from the low or no intensity regions to the high intensity regions. Also, the illuminating light of the first step is preferably applied with an average intensity and duration which allow for efficient diffusion of polymerizing components from the low or no intensity regions to the high intensity regions. Appropriate parameters depend on the given constitution of the LC gel, typical parameters are polymerization wavelength of about 350-450 nm, typically 360 nm, intensity μW-10 mW/cm², typically 0.1 mW, and a polymerization time 1-30 min., typically 10 min. Due to the weak average intensity, the polymerization described in the above is slow and not complete.

In the second illumination step, the cell containing the pre gel mixture is illuminated with flood radiation of high average intensity. Here, the polymerization is completed in all regions. Due to the inhomogeneity created in the first step, the resulting polymer stabilization of the LCs are different in the high and low intensity regions of the first step which thereby form LC gel regions with high polymer network density and LC gel regions with low polymer network density respectively. Throughout this text, these regions will be referred to simply as high/low-network density regions.

Parameters such as the intensity of the polymerizing light and the concentration of the multifunctional reactive monomer are important for obtaining a transparent gel in the field off state and high diffraction efficiency in the field on state. Preferred concentration range of mono-functional monomer is 0-50% and multifunctional is in the range 0-3%. In the most typical embodiment mono-functional is in the range 10-30% and multifunctional in the range 0.5-1%.

In a preferred embodiment, the LC phase further comprises non-linear photo absorber having a nonlinear absorption of the polymerizing light, typically a UV absorber or a dye. The nonlinear absorption component shows a non-linear absorption behavior and above certain intensity, absorption decreases. Thereby, in the most ideal case the nonlinear absorption component reduces the amount of radiation impinging the photoinitiator in the low intensity regions while leaving the high intensity region unaffected. This will increase the effective intensity contrast between lowly and highly illuminated regions and provides high diffraction efficiency in the system. The non-linear photo absorber may e.g. be a photochromic or photo bleaching dye. Examples of such dyes can be found in FIG. 19A through F; salicylidene-anilines (A), stillbenes (B), azo compounds (C) and other photochromic materials such as Spiropyrans (D), fulgides (E) the diarylethenes (F) are also suitable. In these figure general structures of the dyes are shown. R represents subtitutions.

In a third aspect, the invention provides the use of anisotropic liquid crystal gel materials for the fabrication of dynamic holograms.

In a LC gel element wherein the bulk phase has been polymerized, the gel is highly transparent due to the ordered molecular alignment. When an applied voltage exceeds a threshold voltage, the exerted torque from the electric field exceeds the resistance by the polymer network. As a result, LC molecules start reorienting in the direction of the applied electric field. The threshold voltage (V_{c}) of a uniaxially oriented system is given by the equation below.
V_{c}=π(K₁/ε₀Δε)^{0.5} (1)
where K₁ is the splay elastic constant, ε₀ is the permittivity of the free space and Δε is the dielectric anisotropy of the material.

In the dynamic holographic elements according to the invention, regions forming an ordered structure are illuminated first where after the bulk phase is illuminated. The resulting phase contains regions of polymer networks with different crosslink density and thereby different elastic constants and threshold voltage for reorienting the LC molecules.

Hence, in the first and second aspects, polymerized anisotropic LC gel materials preferably comprise low-network density LC gel regions and high-network density LC gel regions formed by exposing the interference pattern inside the LC gel material so that the high-network density LC gel regions form an ordered structure in the low-network density LC gel regions.

Also, in a fourth aspect, the invention provides a dynamic holographic element comprising a cell holding an anisotropic liquid crystal (LC) gel phase, the cell comprising orientation layers to induce macroscopic alignment of the pre gel mixture positioned on top of first and second electrodes positioned on opposite sides of the cell to impose an electric field over the LC gel phase, the LC gel phase comprising low-network density LC gel regions and high-network density LC gel regions,
wherein the high-network density LC gel regions have a larger threshold switching voltage than the low-network density LC gel regions, and
wherein the high-network density LC gel regions form an ordered structure in the low-network density LC gel regions.

The threshold voltage is the voltage which must be applied to the first and second electrodes to induce a realignment of the LC molecules. The network densities in the LC gel influence their ability to change alignment when influenced by an external force and is therefore closely related to the threshold voltage.

When there is no electrical field imposed over the anisotropic LC gel phase, the LC molecules of the low-network density and high-network LC gel regions have at least substantially the same orientation. When a voltage is applied to the electrodes, the electric field will cause a change in the alignment of the LC molecules, which is larger for the low-network density regions than for the high-network density regions. If the applied voltage is lower than the threshold voltage of high-network density regions but higher than the threshold voltage of low-network density regions the change in alignment of the molecules only takes place in low-network density regions.

This is to be seen in contrast to the different regions in PDLC elements. In PDLC, the polymer phase is isotropic and the LC molecules within the system are not macroscopically aligned with respect to each other at zero electric field. As mentioned previously, the pre-PDLC solution was not in a LC state prior to polymerization due to the added components. This means that the LC host molecules were randomly oriented upon polymerization leading to an isotropic polymer matrix. If the polymerization was performed with an interference pattern, droplets of LC host are formed between the isotropic polymer-rich regions. Upon imposing an electric field, the LC droplets align leading to a diffraction contrast between the aligned droplets and the isotropic polymer matrix.

In short, in the LC gel element of the present invention, different regions of already macroscopically aligned (and thereby anisotropic) LCs change alignment differently upon application of an electrical field. In the PDLC element of the prior art, regions (droplets) of non-aligned LCs will start aligning upon application of an electrical field whereas other regions (isotropic polymer-rich matrix) will not.

The ordered structure preferably forms a pattern or a grating representing a reflection, refraction or transmission of light by an object or a component. The structure is ordered so that the low- or high-network density regions are not randomly distributed throughout the LC gel phase.

Preferably, the ordered structure of the high-network density LC gel regions have been formed by exposing an interference pattern inside the LC gel. The ordered structure of the high-network density LC gel regions may be arranged to form a diffraction pattern or grating in the low-network density LC gel regions. The ordered structure of high-network density LC gel regions may form a hologram of an optical component in the low-network density LC gel regions.

Also, the first and second electrodes may each comprise a number of individually addressable electrode parts so that an electrical field can be applied to a selected volume of the LC gel phase

In a fifth aspect, the invention provides a dynamic light emitting setup comprising a dynamic holographic element according to the fourth aspect and one or more first light sources positioned so that light to be emitted from the one or more light source will be transmitted by the dynamic holographic element.

The first light source emits a beam and may include passive optics such as a reflector or a lens to shape the beam. In a preferred embodiment, a first light source is a light emitting diode (LED) having a first primary color.

The light emitting setup may also contain more light emitting diodes emitting other primary colors and their intensity can be controlled individually. In this way the color and/or the color temperature of the light source can be changed by color mixing. When such dynamic holographic element is combined with such a light source, a set up with color as well as beam control is obtained.

The basic differences between PDLCs and LC gels outlined above give rise to a number of advantages of the present invention over the prior art. These advantages of the present invention solve a number of disadvantages of the prior art solution which was realized by the inventors of the present invention.

Due to the anisotropy prior to polymerization, all regions are aligned in the electric field off-state in the LC gel element of the present invention. Upon application of an electrical field, different regions change orientation differently. This provides the advantage that the element will show polarization dependence or birefringence at all times in all states, regardless of the electric field. This is often a requirement in optical set-ups.

In the PDLC element of the prior art, droplets of non-aligned LCs will start aligning upon application of an electrical field whereas the polymer matrix will remain isotropic. Therefore PDLC based holograms are not macroscopically aligned and do not show polarization dependence. This makes them unsuitable if polarization dependent operation is required.

The present invention suggests the use of holography in order to produce structures in LC gels. During holographic illumination, various areas of a LC pre-gel mixture will be illuminated at another intensity leading to formation of regions with different cross-link density in the pre-gel mixture. Cross-link density in the pre-gel mixture determines the threshold voltage (V_{c}) of the corresponding high/low-network density LC gel regions after completed polymerization.

The high- and low-network density LC gel regions of the element according to the invention have different concentrations of polymerized components. Thus, the high- and low-network LC gel regions are different regions of essentially the same phase and have at least substantially the same refractive index along any given axis. This means that it is possible to make the element transparent in the state of zero electrical field so that the hologram appears only during application of an electric field.

In PDLC elements, the LC droplets and the polymer matrix are essentially different phases with different refractive indices. In such an element a hologram is visible in the state of zero electrical field. It is therefore necessary to apply a voltage to reach both the optimum on-state and the optimum off-state so that it is always necessary to use an electric field, which is considered a major disadvantage. Further, such hologram is mostly not in the optimum state as the refractive index difference between the different regions of the hologram is difficult to control. If e.g. the operation temperature is changed, the bias voltage in the field off and field on states will need to be altered.

These and other aspects of the invention will be apparent from and elucidated with reference to the embodiments described hereinafter.

### BRIEF DESCRIPTION OF FIGURES

FIG. 1 is a cross sectional view of a holographic LC element.

FIG. 2 illustrates a setup for forming a holographic grating element according to the present invention.

FIGS. 3A and B show holographic grating elements in an off (V=0) and on (V≠0) state respectively.

FIG. 4 is a graph showing a threshold voltage as a function of a cross linker concentration for various LC gels.

FIG. 5 shows structures of some mono- and multifunctional monomers applicable in the present invention.

FIG. 6 is a graph showing a zero order peak intensity of a grating as a function of a cross linker concentration.

FIG. 7 is a graph showing relative cross linker and concentration.

FIG. 8 is a graph showing a zero order peak intensity of a grating as a function of a dye concentration.

FIG. 9 illustrates a setup for forming a holographic lens element according to the present invention.

FIGS. 10A and B show holographic lens elements in an off (V=0) and on (V≠0) state respectively.

FIGS. 11A and B show the performance of the holographic lens elements in an off (V=0) and on (V≠0) state respectively.

FIGS. 12-17 show structures of some liquid crystal molecules applicable in the present invention.

FIGS. 18 A-C show schematic representations of dynamic holographic elements according to the invention in combination with a light source.

FIGS. 19 A-G show structures of some non-linear absorbers applicable in the present invention.

Figures are preferably schematically drafted in order to facilitate the understanding of the invention. Therefore other designs that could be drafted in the same schematic way are implicitly also disclosed in this document.

### DESCRIPTION OF PREFERRED EMBODIMENTS

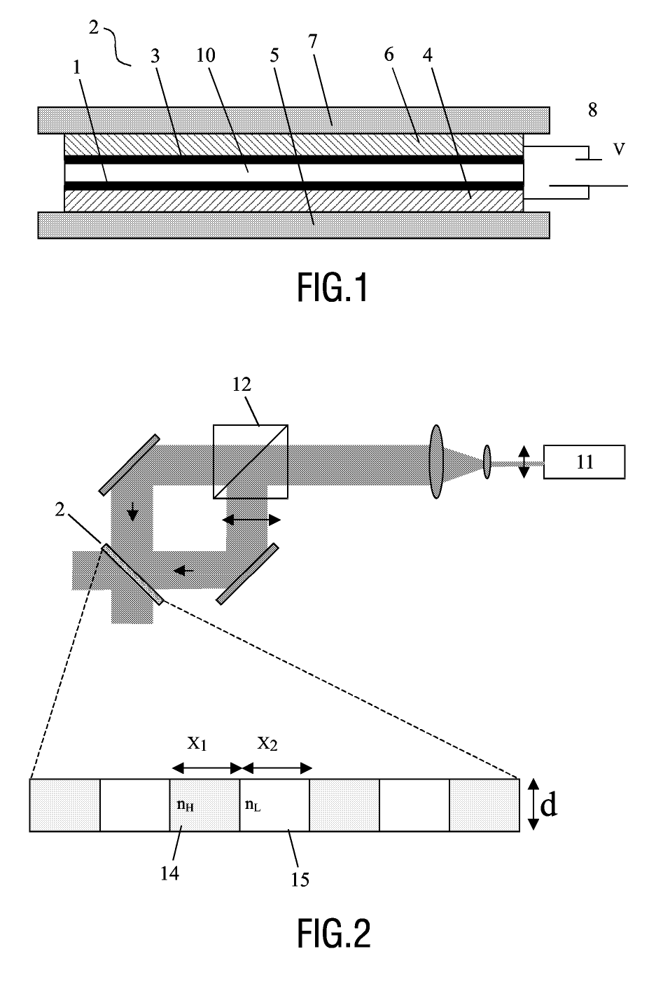

FIG. 1 shows a general layout of a cell 2 used for holographic liquid crystal elements according to the invention. The element comprises a transparent cathode 4 and a transparent anode 6 electrically connected to a power supply 8 for creating an electrical field between these. The electrodes are held by transparent substrates 5 and 7 and encompass a LC gel phase or a LC pre-gel mixture 10. Macroscopic orientation within the pre-gel mixture is induced by orientation layers 1 and 3. These layers are usually made of uniaxially rubbed polymer such as polyimide for planar orientation. In order to induce perpendicular orientation of molecules with respect to surface the orientation layers can chosen to be surfactants. The various kinds of applicable layers are known by those skilled in the art.

FIG. 2 illustrates a simple layout for forming a holographic element. Here, in a first step, a beam from a laser 11 is split by a polarizing beam splitter 12 and then brought together to interfere, forming fringes inside the cell 2 containing a LC pre-gel mixture. Lasers emitting in UV or near UV are very suitable. The interference fringes shown in the exploded view gives a sinusoidal varying illumination of the mixture, and the reactive monomers tend to diffuse to the areas with high intensity to start forming a polymer network. After the first illumination, the cell is exposed to a more intensive flood illumination without the spatial variation whereby the bulk mixture is polymerized. As the first illumination step is limited by diffusion, the first step involves low intensity over longer times whereas the second illumination steps are a higher intensity. As a result, regions 14 and 15 with high and low polymer network density, respectively, are formed, high-density regions switching at much higher voltages than low-density regions. It is important not to have large difference in the refractive indices n_{H} and n_{L} of the regions in order to avoid diffraction in the electric field off state. As the LC gel is anisotropic, it is therefore also important to control the orientation during the illumination steps, e.g. by surface coating of the electrodes or a voltage bias.

Furthermore it is important to have high diffraction efficiency. In order to get high diffraction efficiency from such a grating, the duty ratio should be 50% (i.e. x₁=x₂) and the phase difference needs to be half a wave (i.e. d*[n_{H}−n_{L}]=λ/2).

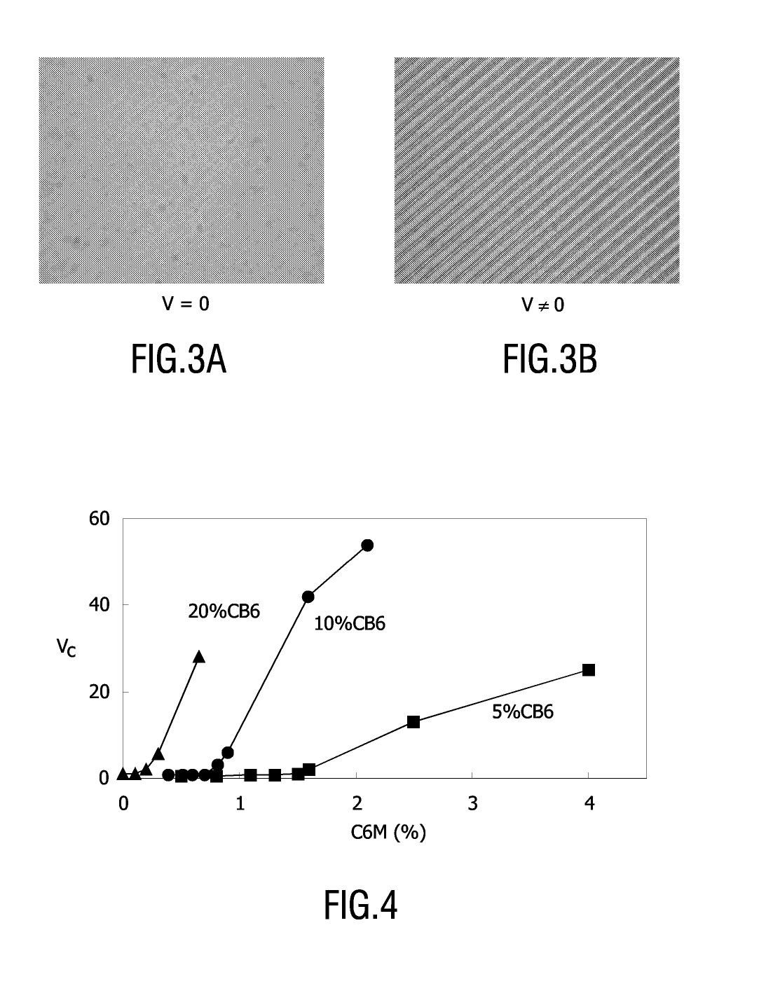

FIGS. 3A and B show optical photographs of the resulting elements at different applied voltage observed between crossed polarizing filters. Areas illuminated during the first step gave regions within the gel with a high threshold voltage. This explains why, when an electric field was applied across the gel, these areas do not switch, and only the areas which was irradiated only in second stage of radiation starts to switch. FIG. 3A and B shows resulting holographic grating elements in an off (V=0) and on (V≠0) state respectively.

In FIG. 4, the threshold voltage V_{c} is plotted as a function of cross linker (C6M) concentration for three different gels having different monofunctional monomer (CB6) concentrations. Hence, the three curves of the graph represent gels formed by polymerizing different amounts of monofunctional monomer, whereas the variation in each curve is related to the degree of polymerization of the given system. The system with the most monomers forms high network densities (i.e. high V_{c}) faster than the system with fewer monomers.

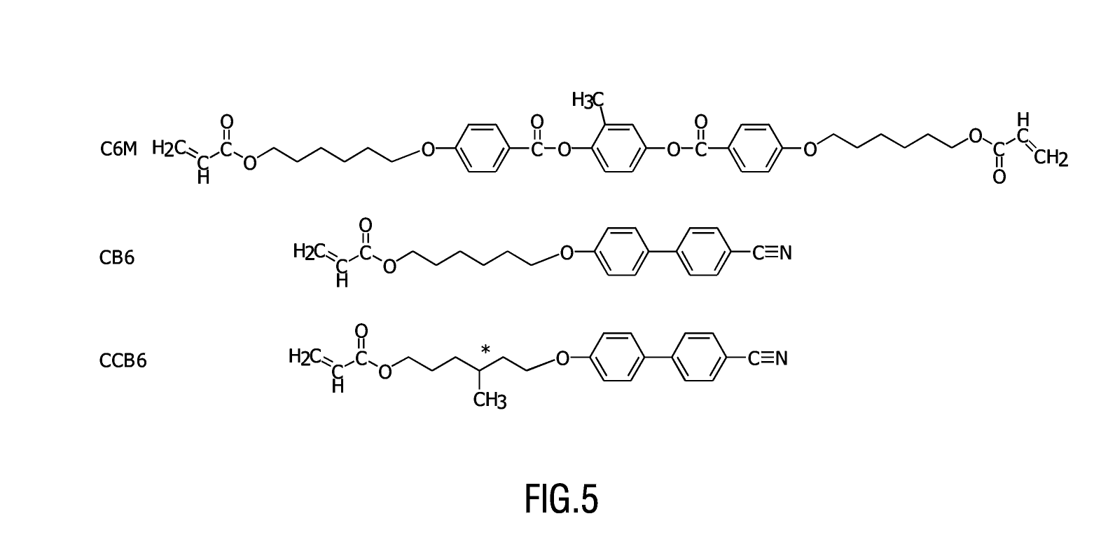

Here, the cross linker is C6M, a diacrylate shown in FIG. 5 and the monofunctional monomer is CB6, a monoacrylate also shown in FIG. 5. FIG. 5 also shows the structure of another, chiral monoacrylate CCB6. The photoinitiator concentration in the mixtures was 0.5% and the intensity of the UV light was 1 mW/cm².

It can also be seen that the threshold voltage remained constant up to a certain cross linker concentration, above which the threshold voltage rapidly increases. The fact that the threshold voltage shows an increase above a critical concentration indicates that the elastic constant in the expression (1) for the threshold voltage shows an increase above this concentration, corresponding to the gel-point of the system. At this concentration a three-dimensional network is created by the side-chain polymers formed by the monoacrylate molecules cross-linked by the diacrylate molecules. It can be seen from FIG. 4 that there is an inverse relationship between the monomer and cross linker concentrations necessary to reach the gel-point. Furthermore, for gels with high monomer concentrations, the increase in V_{c} above the gel-point is much faster than for gels with lower monomer concentrations.

In the following, we describe two different anisotropic gel systems used to study holographic recording. One of the systems is uniaxially oriented gel with a positive birefringence “Gel 1”. The other system is a gel with a negative birefringence “Gel 2”. Gel 2 is obtained using a chiral system with a very short pitch comparable that of the wavelength of light. Such a twisted configuration gives the system negative birefringence. Furthermore such a negative birefringent system has the property of showing no polarization direction dependence for light falling perpendicular to the cell.

The Gel 1 system comprises
photoinitiator irgacure 651 (0.5%)
diacrylate C6M (variable)
monoacrylate CB6 (20%)
non reactive liquid crystal E7 (80%)

The Gel 2 system comprises
photoinitiator irgacure 651 (0.5%)
diacrylate C6M (variable)
chiral monoacrylate CCB6 (20%)
chiral CB15 (35%)
non reactive liquid crystal BL98 (45%)

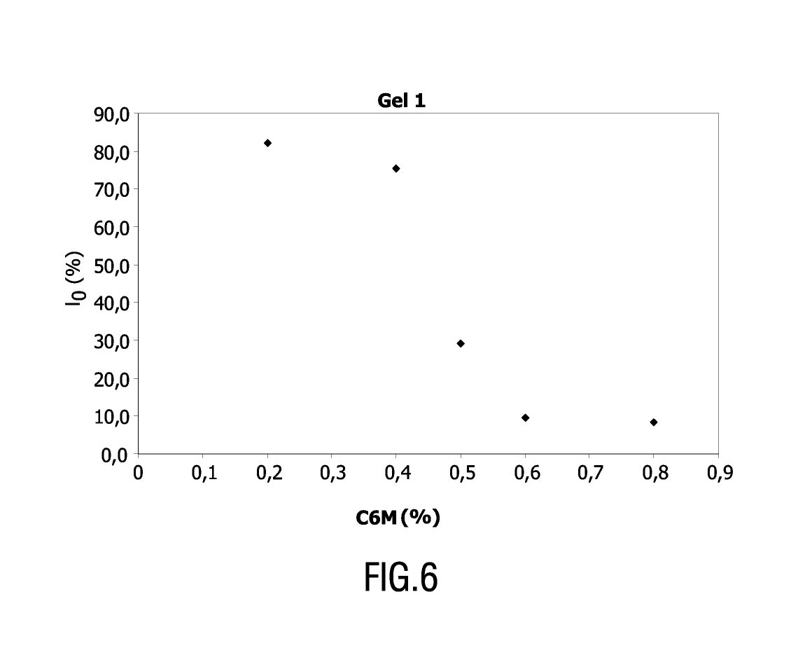

We produced gratings using the holographic set up shown in FIG. 2 where the period of the fringes was 10 μm. We estimated the efficiency of the gratin by measuring the zero order peak intensity I₀. For the Gel 1 system, I₀ was measured as a function of the cross linker (C6M) concentration, and the result is plotted in the graph of FIG. 6. From FIG. 6 it can be seen that the intensity of the zero order shows a rapid decrease at around 0.5% cross linker concentration. This point determines the onset of efficient diffraction and is critically dependent on the relative cross linker and monomer concentrations.

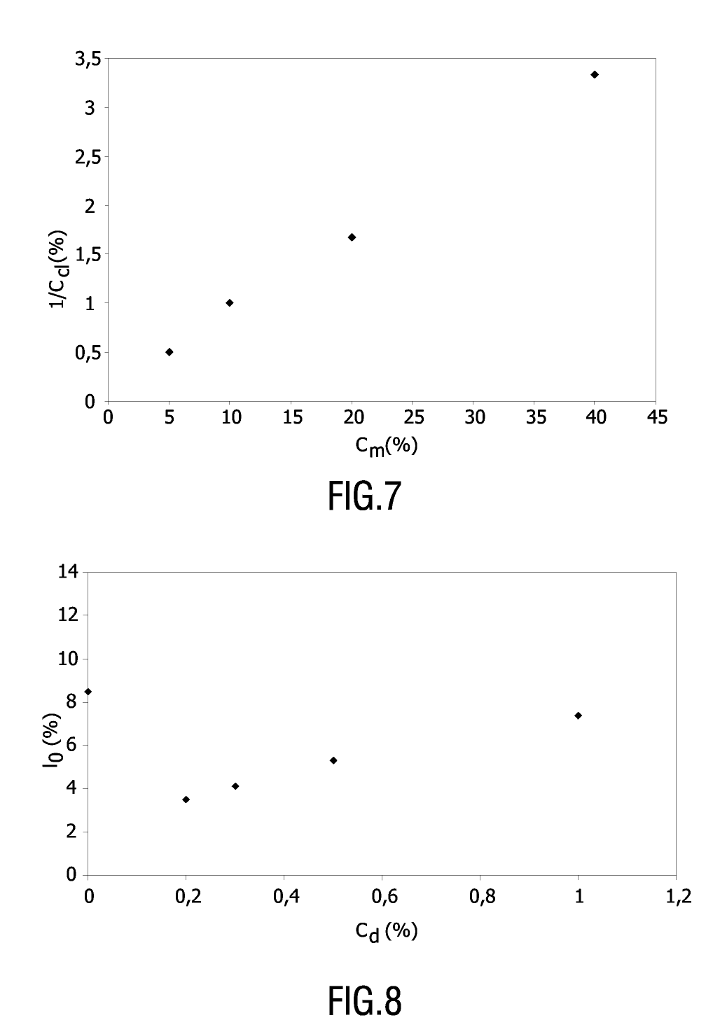

A series of measurements of how much diacrylate (cross linker) was necessary with a given monoacrylate (monomer) concentration for a system to reach the onset of good diffraction efficiency was conducted. FIG. 7 shows the results in a graph of inverse cross linker concentration 1/C_{cl} as a function of monomer concentration Cₘ. From FIG. 7 it can be determined that there is an inverse relationship between monomer and cross linker concentrations necessary to reach the onset of efficient diffraction.

A linear regression of the curve of FIG. 7 yields the relationship
C_{crosslink}⁻¹=0.08·Cₘₒₙₒₘₑᵣ+0.13 (2)
which may be used as a guideline for determining proper relative amounts of cross linker and monomer.

It was also determined that the intensity of the zero order peak from gratings could be decreased further when the system was provided with a nonlinear photo absorber, e.g. a dye, in the LC pre-gel mixture. FIG. 8 shows a graph of the zero order peak intensity I₀ versus a dye concentration C_{d} for a grating formed by holographic illumination of the following mixture:
irgacure 651 (0.5%)
diacrylate C6M (0.8)
chiral monoacrylate CCB6 (20%)
chiral CB15(35%)
non reactive LC BL98 (45%)
dye molecule 11646 (variable, C_{d})

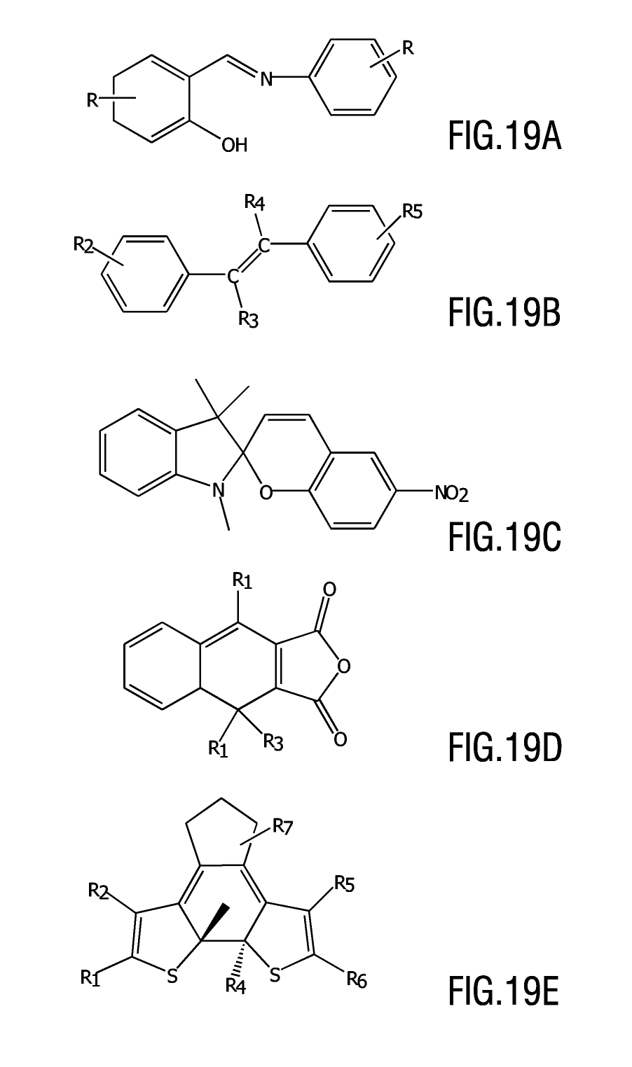

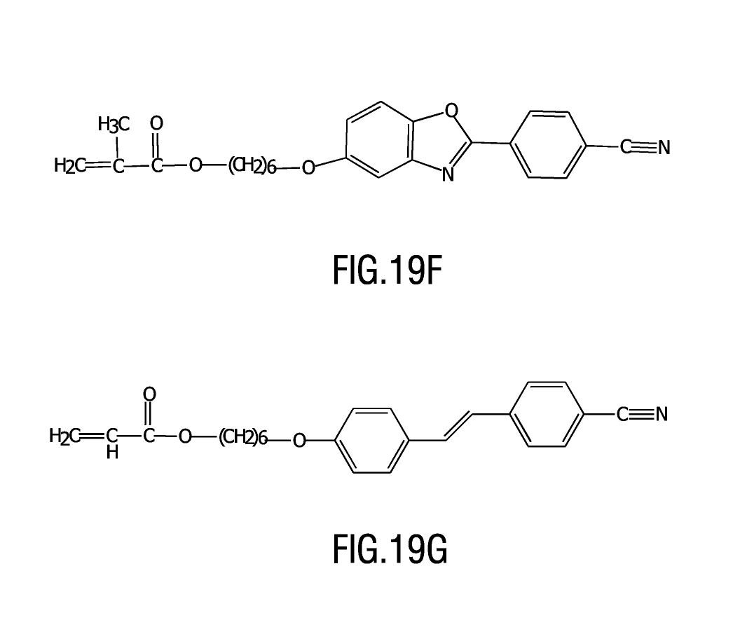

As can be seen, the addition of dye increases the diffraction efficiency considerably; from I₀=8.5 at zero dye concentration to I₀=3.5 at 0,2% dye concentration. Adding more dye slowly deteriorates the extinction of the zero order, most likely by introducing more scattering in the system. It appears that the optimum dye concentration is to be in the interval 0<C_{d}≦0.2%, at least for dye molecule 11646. Another dye molecule 457 was also found be working effectively. The structure of these dyes is shown in FIGS. 19F and G.

The effect of the nonlinear absorption component is attributed to its strong absorption at low intensities and weak absorption at high intensities. Thereby, in the fringe pattern shown in FIG. 2, the nonlinear absorption absorbs radiation mainly in the low intensity regions 15 and thereby reduces the illumination of the photoinitiator and thereby polymerization in these regions. This will increase the effective intensity contrast between highly and lowly illuminated regions 14 and 15 and thereby the diffraction efficiency of the system.

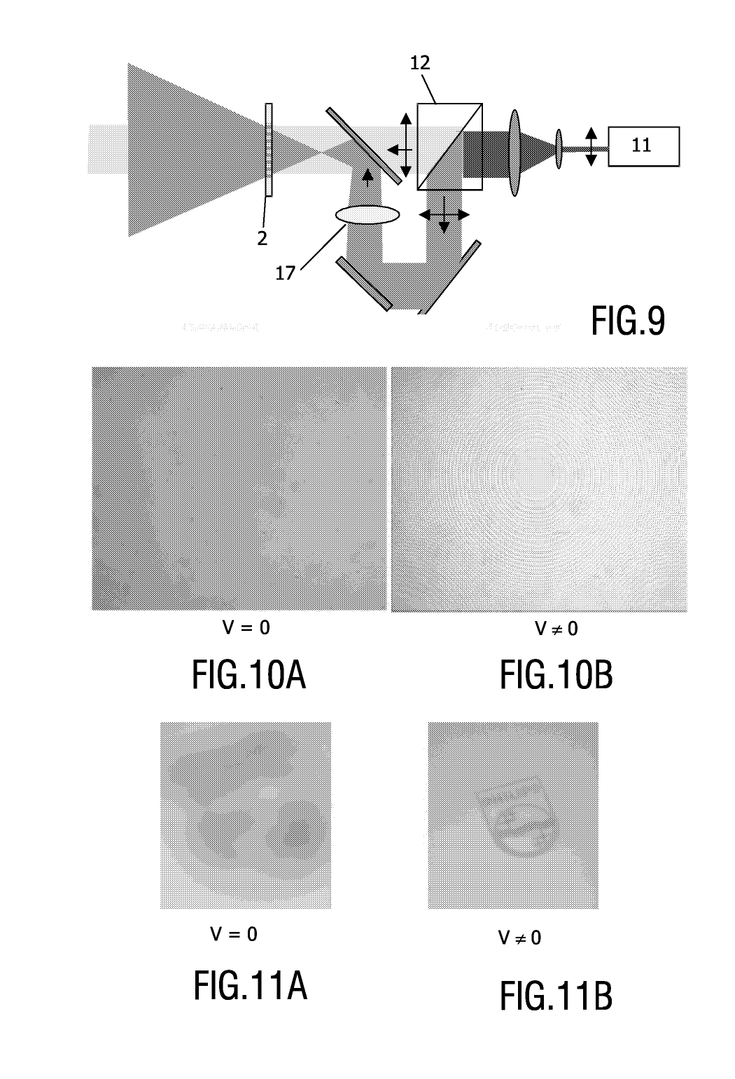

FIG. 9 shows a set-up similar to the set-up of FIG. 2. Here, a cell 2 containing a LC pre-gel mixture is illuminated by an interference pattern of a lens 17. The pattern is generated by overlapping two coherent beams, one of which is the image plane of lens 17. This setup was used to record a lens function in the cell 2. The resulting dynamic hologram is transparent in the field off state, and FIGS. 10A and B show the element in voltage off/on states. FIGS. 11A and B shows the use of the fabricated dynamic hologram in forming an image of a logo. The hologram of the lens was held between a camera and the logo and pictures 11A and B was taken with V=0 and V≠0 respectively.

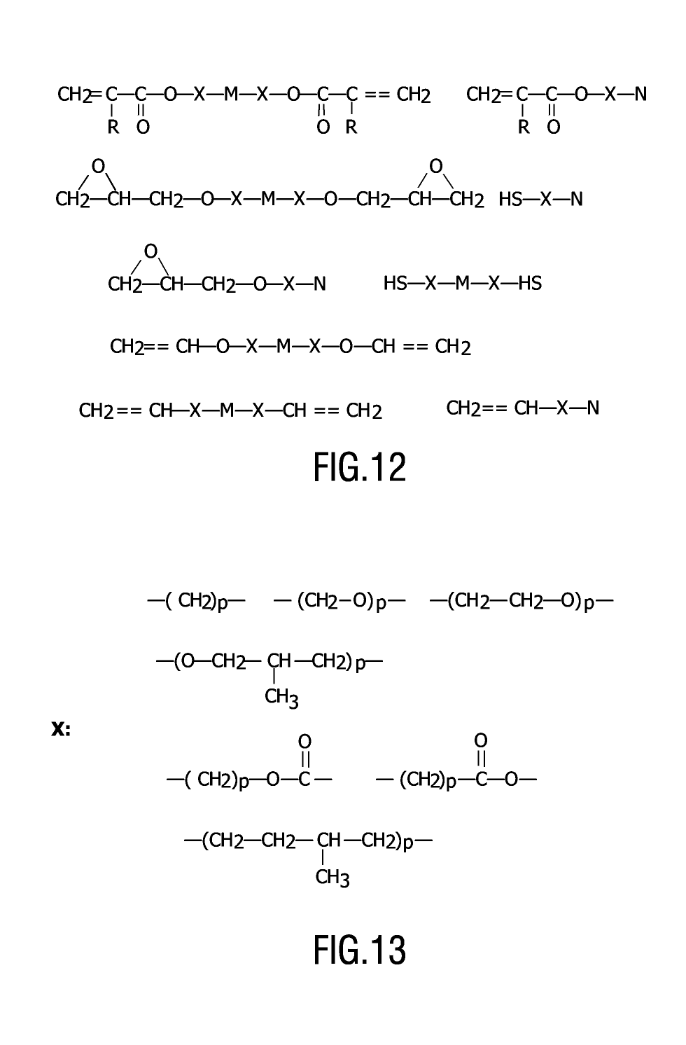

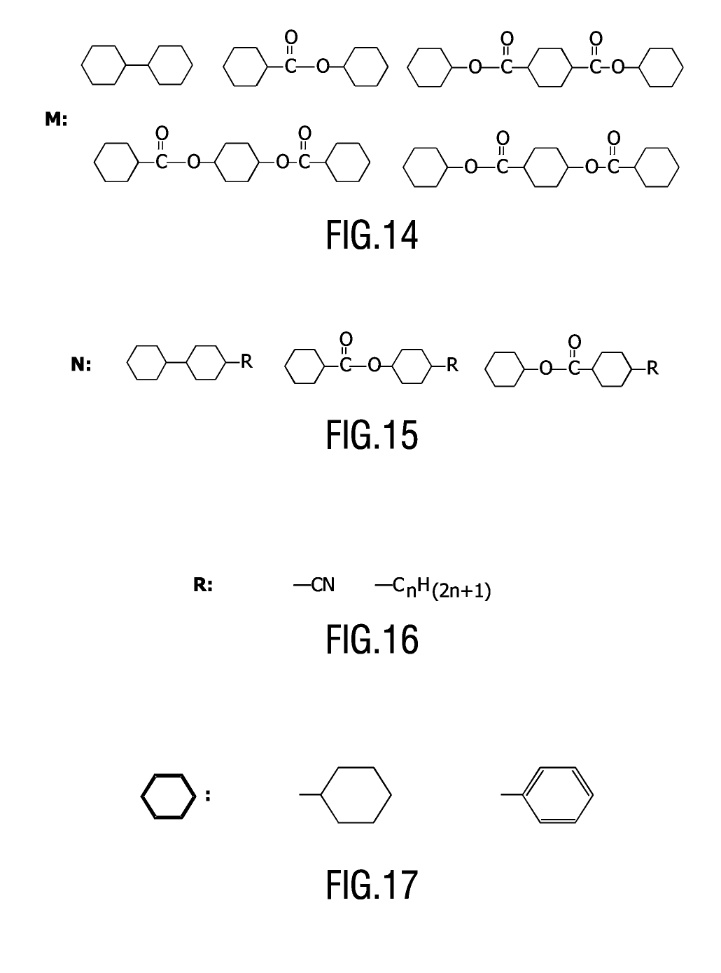

There are a large number of molecules, which can be used as the liquid crystal host in a LC pre-gel mixture. Structures of a non-exclusive list of applicable LC molecules are shown in FIG. 12. Options for the variable groups X, M, and N of the structures in FIG. 12 are shown in FIGS. 13-15. Options for the variable groups R and [symbol] of the structures in FIGS. 14 and 15 are shown in FIGS. 16 and 17.

In the above description, the fabrication of dynamic LC gel holographic elements of a grating and a lens is shown. It is possible for the person skilled in the art to produce dynamic LC gel holographic elements representing any other optical components.

Such optical elements can be used in combination with a light source with or without beam shaping optics. The holographic element can be placed in such a system in order to dynamically alter the shape or direction of the light beam.

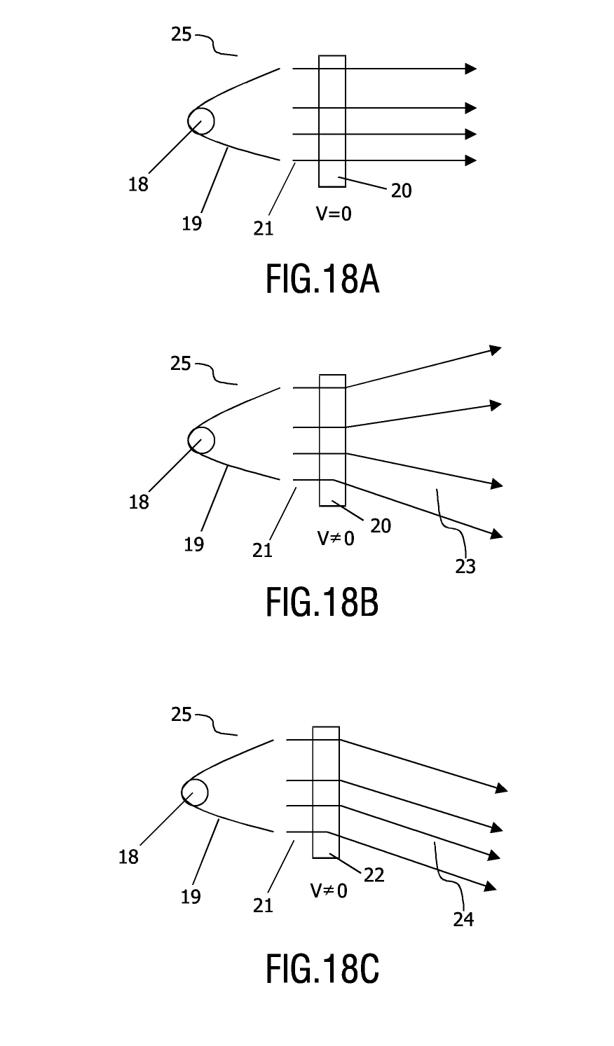

FIG. 18A schematically shows a light emitting setup 25 dynamic holographic element 20 in combination with a light source 18. The light source includes passive optics 19 to form a collimated beam 21 incident on the holographic element 20. When the holographic element 20 is off (V=0), it does not deflect incident beam 21 as shown in FIG. 18A. A preferred light source is an LED.

Upon switching the holographic element 20 on (V≠0) using a voltage source, the ordered structure of the hologram cause the incident beam to diverge as shown in FIG. 18B. As can be seen, the holographic element 20 has the function of a divergent lens or a lens array and can be fabricated using a set-up such as the one shown in FIG. 9 with a divergent lens or a lens array in place of the component 17.

FIG. 18C shows the same setup with another holographic element 22 having another function. Here, beam 21 is deflected as the holographic element 22 has the function of a grating, which can be fabricated according to the set-up such as the one shown FIG. 2.

The light source may emit a white light. However it may also consist of a plurality of light sources emitting different primary colors, typically light emitting diodes. If the intensity of the light sources emitting the different colors can be individually controlled, then the color and/or the color temperature of the light can also be adjusted. When such light source is combined with a dynamic hologram a dynamic light source with color and beam control can be obtained.

In the above description the term “comprising” does not exclude other elements or steps and “a” or “an” does not exclude a plurality. Furthermore the terms “include” and “contain” does not exclude other elements or steps.

1. A hologram formed by exposing an interference pattern of polymerizing light inside an anisotropic LC pre-gel mixture and thereafter exposing the bulk mixture to the polymerizing light.

2. The hologram according to claim 1 wherein polymerized anisotropic LC gel mixture comprise low- network LC gel regions and high-network density LC gel regions formed by exposing the interference pattern inside the LC gel mixture so that the high-network density LC gel regions form an ordered structure in the low-network density LC gel regions.

3. The use of an anisotropic liquid crystal pre-gel mixture for the fabrication of dynamic holograms.

4. A dynamic holographic element comprising a cell containing an anisotropic liquid crystal (LC) gel phase, the cell comprising orientation layers positioned on top of first and second electrodes positioned on opposite sides of the cell to impose an electric field over the LC gel phase, the LC gel phase comprising high-network density LC gel regions and low-network density LC gel regions,
wherein the high-network density gel regions have a larger threshold switching voltage than the low-network density LC gel regions, and
wherein the high-network density LC gel regions form an ordered structure in the low-network density LC gel regions.

5. The dynamic holographic element according to claim 4, wherein the ordered structure of the high-network density LC gel regions is a holography formed by exposing an interference pattern inside a LC pre-gel mixture.

6. The dynamic holographic element according to claim 4, wherein the ordered structure of the high-network density and low-network density LC gel regions form a diffraction pattern or grating.

7. The dynamic holographic element according to claim 4, wherein the ordered structure of the high-network density and low-network density LC gel regions form a hologram of an optical component.

8. The dynamic holographic element according to claim 4, wherein the high- and low-network density LC gel regions have at least substantially the same refractive indices at zero electric field.

9. The dynamic holographic element according to claim 4, wherein the high- and low-network density LC gel regions are macroscopically aligned.

10. The dynamic holographic element according to claim 4, characterized in that the element is transparent when there is no electric field over the LC gel phase.

11. A light emitting setup comprising a dynamic holographic element according to claim 4 and one or more first light sources positioned so that light to be emitted from the one or more light source will be transmitted by the dynamic holographic element.

12. The light emitting setup according to claim 11, wherein a first light source is a light emitting diode having a first primary color.

13. The light emitting setup according to claim 12, further comprising a second light source being a light emitting diode having a second primary color different from the first primary color, wherein intensities of the first and second light source are individually adjustable.

14. A method for forming a dynamic holographic element, the method comprising the steps of:
providing an anisotropic LC pre-gel mixture comprising:
a non-reactive LC host;
mono functional polymerizable monomer;
multifunctional reactive monomer; and
a photoinitiator
illuminating parts of the LC pre-gel mixture with an interference pattern of polymerizing light forming high intensity regions and low or no intensity regions in the LC pre-gel mixture, and
illuminating the LC pre-gel mixture with polymerizing light to form an anisotropic LC gel.

15. The method according to claim 14, wherein the polymerizable LC monomer comprises monomers of acrylate, epoxy, vinylether or a thioleene system.

16. The method according to claim 14, wherein the LC pre-gel mixture further comprises a non-linear photo absorber.

17. The method according to claim 14, wherein the step of illuminating parts of the LC phase comprises initiating polymerization in the high intensity regions and diffusion of polymerizing components from the low or no intensity regions to the high intensity regions.

18. The method according to claim 14, wherein a scale of intensity variations in fringes of the interference pattern are adapted to allow for efficient diffusion of polymerizing components from the low or no intensity regions to the high intensity regions on a given time scale.
